(19) United States
(12) Patent Application Publication
(10) Pub. No.: US 2026/0051545 A1
(43) Pub. Date: Feb. 19, 2026

(54) METHOD FOR SORTING ALL-SOLID-STATE BATTERY OF CONFORMING PRODUCT

(71) Applicants: Hyundai Motor Company, Seoul (KR); Kia Corporation, Seoul (KR)

(72) Inventors: Sung Ju Cho, Hwaseong (KR); Ju Min Kim, Hwaseong (KR); Jong Hwan Choi, Hwaseong (KR); Yong Hun Lee, Hwaseong (KR); Hyun Geun Kwon, Hwaseong (KR); Yong Jun Lee, Hwaseong (KR); Tae Young Kwon, Hwaseong (KR); Yoon Seon Kim, Hwaseong (KR)

(21) Appl. No.: 19/088,557

(22) Filed: Mar. 24, 2025

(30) Foreign Application Priority Data
Aug. 19, 2024 (KR) 10-2024-0110815

(51) Int. Cl. H01M 10/058; G01R 31/389; H01M 10/04

(52) U.S. Cl. CPC H01M 10/058; G01R 31/389; H01M 10/0468

(57) ABSTRACT

A method of determining conforming or non-conforming all-solid-state batteries includes stacking and pressing a cathode, an anode, and a solid electrolyte layer, measuring the cell's resistance in a high frequency region and an ultra-high frequency region, and sorting the cell based on the measured values. Specific frequency windows (for example, about 2-4 kHz or 30-70 kHz) and numeric thresholds (e.g., resistance of 100-150 mΩ for the high frequency region or 80-200 mΩ for the ultra-high frequency region) are used as criteria for determining if the battery meets conformity requirements. A conforming unit cell can further exhibit an initial capacitance at least 90% of its design capacitance. The method can also include discarding or reworking non-conforming pressed structures and proceeding with further battery-manufacturing steps only for conforming cells, enhancing production efficiency and ensuring high-quality final products.

### CROSS-REFERENCE TO RELATED APPLICATION

This application claims under 35 U.S.C. § 119 (a) the benefit to Korean Patent Application No. 10-2024-0110815, filed in the Korean Intellectual Property Office on Aug. 19, 2024, the entire contents of which are incorporated herein by reference.

### BACKGROUND

### Technical Field

The present disclosure relates to a method for sorting an all-solid-state battery of conforming product, capable of effectively sorting the all-solid-state battery of conforming product in an assembly process step including a pressing process and a cell stacking process in a manufacturing process of the all-solid-state battery.

### Background

Studies and research have been conducted on various batteries to overcome the limitation of a lithium secondary battery in the capacity of a battery, the stability of the battery, the power of the battery, the increase in the size of the battery, or the decrease in the size of the battery. Among them, an all-solid-state battery refers to a battery having a solid electrolyte instead of a liquid electrolyte having been employed in a conventional lithium secondary battery. According to the all-solid-state battery, as a flammable solvent is not used inside the battery, the risk of firing or explosion, which has occurred due to the decomposition reaction of the conventional electrolyte, is removed, so stability is significantly improved.

The all-solid-state battery includes a three-stage stack structure including a cathode composite layer bonded to a cathode current collector, an anode composite layer bonded to an anode current collector, and a solid electrolyte interposed between a cathode and an anode. The all-solid-state battery is manufactured through an electrode preparing process, an assembling process, and an activating process. In particular, the assembling process includes an electrode punching process, an electrode stacking process, a pressing process, a cell stacking process, a tab welding process, and a packaging process.

Meanwhile, since the all-solid-state battery has a characteristic different from a characteristic of a conventional lithium secondary battery, the all-solid-state battery of conforming product should be sorted in a different criterion in the manufacturing process of the all-solid-state battery. According to the conventional lithium secondary battery, a part resistance of a cell is measured through resistance measurement under a higher frequency condition in a wetting step after injecting, thereby determining the conduction failure of the cell or the level of the part resistance. Meanwhile, since the all-solid-state battery does not employ a liquid electrolyte, the injecting step is not employed in the manufacturing process of the all-solid-state battery. In addition, since the all-solid-state battery employs a solid electrolyte as an electrolyte, a resistance at a grain boundary and a resistance at an interlayer interface should be considered to determine the all-solid-state battery being conforming product. Accordingly, the criterion of determining conforming product of the conventional lithium secondary battery is difficult to be identically applied to the all-solid-state battery.

Accordingly, there is required a novel method for conforming product, which is optimally applied to and limited to an all-solid-state battery.

### SUMMARY

The present disclosure has been made to solve the above-mentioned problems occurring in the prior art while advantages achieved by the prior art are maintained intact.

An aspect of the present disclosure provides a method for sorting an all-solid-state battery of conforming product.

More specifically, the present disclosure provides a method for sorting an all-solid-state battery of conforming product, in which the resistance characteristics at a grain boundary and an interlayer interface, which result from the structural characteristic of the all-solid-state battery, is determined by using two resistances measured in the high frequency region and the ultra-frequency region, thereby easily sorting a failed battery in the assembling process. Accordingly, the product yield rate in the final stage may be increased, and the quality of the all-solid-state battery in the final stage may be improved.

The technical problems to be solved by the present disclosure are not limited to the aforementioned problems, and any other technical problems not mentioned herein will be clearly understood from the following description by those skilled in the art to which the present disclosure pertains.

To accomplish the object, the present disclosure provides a method for sorting an all-solid-state battery of conforming product.

More specifically, (1) The present disclosure provides a method for sorting an all-solid-state battery of conforming product including measuring resistances of a unit cell in a high frequency region and an ultra-high frequency region after pressing of the unit cell in which a cathode, a solid electrolyte layer, and an anode (S1), and determining whether the unit cell is conforming product, based on the resistances of the unit cell measured in the high frequency region and the ultra-high frequency region (S2).
(2) The present disclosure provides a method for sorting an all-solid-state battery of conforming product, in which the high frequency region is a frequency region ranging from 0.01 kHz to 10 KHz in (1).
(3) The present disclosure provides a method for sorting an all-solid-state battery of conforming product, in which the high frequency region is a frequency region ranging from 2 kHz to 4 kHz in (1) or (2).
(4) The present disclosure provides a method for sorting an all-solid-state battery of conforming product, in which the ultra-high frequency region is a frequency region ranging from 10 kHz to 100 kHz, in any one (1) to (3).
(5) The present disclosure provides a method for sorting an all-solid-state battery of conforming product, in which the ultra-high frequency region is a frequency region ranging from 30 kHz to 70 kHz, in any one (1) to (4).
(6) The present disclosure provides a method for sorting an all-solid-state battery of conforming product, in which the unit cell is determined as being conforming product, when the resistance in the high frequency region ranges from 100 mΩ to 150 mΩ in S2, in any one of (1) to (5).
(7) The present disclosure provides a method for sorting an all-solid-state battery of conforming product, in which the unit cell is determined as being conforming product, when the resistance in the ultra-high frequency region ranges from 80 mΩ to 200 mΩ in S2, in any one of (1) to (6).
(8) The present disclosure provides a method for sorting an all-solid-state battery of conforming product, in which the unit cell is determined as being conforming product, when the unit cell has the resistance in the ultra-high frequency region which is greater than the resistance in the high frequency region in S2, in any one of (1) to (7).
(9) The present disclosure provides a method for sorting an all-solid-state battery of conforming product, in which the unit cell is determined as being conforming product, when a ratio of the resistance in the ultra-high frequency region to the resistance in the high frequency region ranges from 1.2 to 2.0, in any one of (1) to (8).
(10) The present disclosure provides a method for sorting an all-solid-state battery of conforming product, in which the unit cell determined as being conforming product has an initial capacitance which is at least 90% of a design capacitance of the unit cell, in any one of (1) to (9).

In some embodiments, a method for sorting an all-solid-state battery of conforming product includes: stacking a cathode, a solid electrolyte layer, and an anode to form a unit cell; pressing the unit cell; measuring a resistance of the pressed unit cell in a high frequency region and a resistance of the pressed unit cell in an ultra-high frequency region; and determining whether the pressed unit cell is a conforming product based on the measured resistances in the high frequency region and the ultra-high frequency region.

The high frequency region may be a frequency region ranging from about 2 kHz to about 4 kHz.

The ultra-high frequency region may be a frequency region ranging from about 30 kHz to about 70 KHz.

The pressed unit cell may be determined to be conforming when a resistance of the pressed unit cell in the high frequency region is from about 100 mΩ to about 150 mΩ.

The pressed unit cell may be determined to be conforming when a resistance of the pressed unit cell in the ultra-high frequency region is from about 80 mΩ to about 200 mΩ.

The pressed unit cell may be determined to be conforming when the measured resistance in the ultra-high frequency region is greater than the measured resistance in the high frequency region.

The pressed unit cell may be determined to be conforming when a ratio of the resistance in the ultra-high frequency region to the resistance in the high frequency region ranges from about 1.2 to about 2.0.

In some embodiments, a method of manufacturing an all-solid-state battery includes: stacking a cathode, a solid electrolyte layer, and an anode to form a stack structure; pressing the stack structure; measuring a resistance of the pressed stack structure in a high frequency region and a resistance of the pressed stack structure in an ultra-high frequency region; sorting the pressed stack structure as a conforming product or a non-conforming product based on the measured resistances in the high frequency region and the ultra-high frequency region; and performing one or more subsequent battery-manufacturing steps on the pressed stack structure sorted as the conforming product.

The pressing may be performed at a pressure of about 450 MPa and a temperature of about 100° C.

Any pressed stack structure identified as a non-conforming product may be discarded or reworked prior to performing the one or more subsequent battery-manufacturing steps. As discussed, the method and system suitably include use of a controller or processer.

### DETAILED DESCRIPTION

Hereinafter, the present disclosure will be described in more detail.

The terminology or words used in the present specification and the claims shall not be interpreted as commonly-used dictionary meanings, but should not be interpreted as to be relevant to the technical scope of the present disclosure based on the fact that the inventor may properly define the concept of the terms to explain the present disclosure in best ways.

The term “all-solid-state battery” used herein refers to a battery in which a solid electrolyte is employed in place of a conventional liquid electrolyte, thereby substantially reducing or eliminating leakage and combustion risks associated with liquid electrolytes.

The term “unit cell” used herein refers to an electrochemical cell comprising at least one cathode, one anode, and a solid electrolyte layer interposed between the cathode and the anode, which can be repeatedly stacked or combined to form a larger battery assembly.

The term “grain boundary” used herein refers to an interface within the solid electrolyte (or electrode) materials, where two adjacent crystalline grains meet, potentially influencing ion conduction properties and overall battery performance.

The term “pressing” or “pressing process” used herein refers to applying physical pressure—optionally with controlled heat—to the stacked cathode, anode, and solid electrolyte layers in order to improve interfacial contact and reduce voids between the layers.

The term “initial capacitance” used herein refers to the battery's measured capacity, or stored charge, at the outset of its operational life (e.g., after final assembly and a first activation cycle), which may be compared against a theoretical or “design capacitance.”

The term “design capacitance” used herein refers to the theoretical or targeted capacity of the battery cell based on electrode loading, material formulations, and other design parameters established prior to fabrication.

The term “conforming product” used herein refers to a battery or unit cell that meets or exceeds predetermined electrical and structural quality criteria, such as specific resistance thresholds or a required level of initial capacitance.

The term “micro-short” used herein refers to a partial or localized short-circuiting within the battery layers, generally stemming from improper contact or defects that can lead to undesired self-discharge or capacity loss.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules, and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

An all-solid-state battery has a structure including a solid electrolyte layer between a cathode and an anode, instead of a separator and an electrolyte solution, which is different from a conventional lithium-ion battery. Accordingly, when a manner for sorting a lithium-ion battery of conforming product is applied to the all-solid-state battery, an effective result may not be obtained. Accordingly, a novel method for sorting an all-solid-state battery of conforming product needs to be suggested by sufficiently considering a material and a system characteristic of the all-solid-state battery. To this regard, the present disclosure provides a method for sorting an all-solid-state battery of conforming product, capable of determining the conforming product of the all-solid-state battery using resistances in a high frequency region and in an high frequency region, which are to be measured with respect to a unit cell of an all-solid-state battery formed through a pressing process for a stack structure after stacking a cathode, a solid electrolyte layer, and an anode.

Hereinafter, the method for sorting an all-solid-state battery of conforming product according to the present disclosure will be described in detail.

Method for Sorting all-Solid-State Battery of Conforming Product

The present disclosure provides a method for sorting an all-solid-state battery of conforming product including measuring resistances of a unit cell in a high frequency region and an ultra-high frequency region after pressing the unit cell in which a cathode, a solid electrolyte layer, and an anode are stacked (S1), and determining whether the unit cell is conforming product, based on the resistances of the unit cell measured in the high frequency region and the ultra-high frequency region (S2).

The resistances in mutually different frequency regions, which are obtained with respect to the unit cell, may represent a resistance by a cell part and a resistance on the interface between the solid electrolyte layer and the electrode, respectively. Whether the all-solid-state battery is conforming product in the final stage is determined, based on both resistances.

Meanwhile, according to the present disclosure, the cathode, the anode, and the solid electrolyte layer of the unit cell, which serves as a target for the determination of conforming product, may be a cathode, an anode, and a solid electrolyte layer employed for a conventional all-solid-state battery. More preferably, the cathode may include a cathode layer formed on a cathode current collector, and the cathode layer may include a cathode active material and a solid electrolyte. The anode may include an anode layer formed on an anode current collector, and the anode layer may include an anode active material and a solid electrolyte. The solid electrolytes, which may be included in the solid electrolyte layer, the cathode and the anode, may be sulfide-based solid electrolytes.

Hereinafter, the method for sorting the all-solid-state battery of conforming product will be described step by step.

### Measuring of Resistances (S1)

To sort the all-solid-state battery of conforming product, the resistances of the unit cell in the high frequency region and the ultra-high frequency region should be measured. In the present step, the unit cell to be measured for the resistances may have a structure including a cathode, an anode, and a solid electrolyte layer positioned between the anode and the solid electrolyte layer. The resistances of the unit cell may be measured by performing a pressing process for a stack structure after stacking the cathode, the solid electrolyte layer, and the anode. When the resistances are measured before the pressing process, and then the pressing process is performed, the measured resistances fail to sufficiently represent the quality of an all-solid-state battery which is a final product.

An equipment employed to measure the resistances in the present step may be a conventional resistance measuring equipment. For example, a conventional resistance measuring equipment, such as Hioki's IM3590, may be employed. When the resistances are measured using the equipment, a measuring temperature condition may range from −30° C. to 60° C. Preferably, the measuring temperature condition may be at least −30° C., at least −20° C., at least −10° C., at least 0° C., at least 10° C., or at least 20° C., and at most 60° C., at most 50° C., at most 40° C., or at most 30° C.

Meanwhile, in the present step, the high frequency region, which is a resistance measuring condition, may range from 0.01 kHz to 10 KHz. Preferably, the high frequency region may be at least 0.01 kHz, at least 0.1 kHz, at least 0.5 kHz, at least 1 kHz, or at least 2 kHz, and at most 10 kHz, at most 8 kHz, at most 6 kHz, or at most 4 kHz. In addition, the ultra-high frequency region, which is a resistance measuring condition, may range from 10 kHz to 100 kHz. Preferably, the ultra-high frequency region may be at least 10 kHz, at least 15 kHz, at least 20 kHz, or at least 30 kHz, and at most 100 kHz, at most 90 kHz, at most 80 kHz, or at most 70 kHz. The resistances measured in the high frequency region and ultra-high frequency region are highly associated with whether the all-solid-state battery in the final stage is conforming product. In more detail, the resistance measured in the high frequency region may be an index for indicating the resistance of a part of a cell, and the resistance measured in the ultra-high frequency region may be an index for indicating the resistance on the interface a cell of the all-solid-state battery.

### Determining Whether Unit Cell is Conforming Product (S2)

After measuring the resistances of the unit cell in the high frequency region and the ultra-high frequency region in ‘S1’ describe above, Whether the all-solid-state battery is conforming product is determined based on the resistances of the unit cell, which is measured.

In more detail, the resistance of the part of the cell may be estimated based on the resistance measured in the high frequency region, and the resistance on the interface may be estimated based on the resistance measured in the ultra-frequency region. The all-solid-state battery satisfying specific conditions in the resistance of the part of the cell and the resistance on the interface may be determined as being conforming product.

In more detail, in S2, the unit cell having the resistance, which ranges from 100 mΩ to 150 mΩ, in the high frequency region may be determined as being conforming product. In S2, the unit cell having the resistance, which ranges from 80 mΩ to 200 mΩ, in the ultra-high frequency region may be determined as being conforming product. When the resistance in the high frequency region is in the above range, the part resistance of the all-solid-state battery may be determined as indicating conforming product. When the resistance in the high frequency region is significantly low, the short failure may be indicated. When the resistance in the high frequency region is significantly high, it may be indicated that errors may be caused in ion conduction or electron conduction of the all-solid-state battery to reduce the capacitance and the power. When the resistance in the ultra-high frequency region is in the above range, the resistance on the interface of the all-solid-state battery may be determined as indicating conforming product. When the resistance in the ultra-high frequency region is significantly high, it may be indicated that the contact failure is caused on the interface. When the resistance in the ultra-high frequency region is excessively low, it may be indicated that a failure is caused due to the short between the cathode/anode.

Furthermore, in S2, a unit cell having the resistance in the high frequency region which is greater than the resistance in the ultra-high frequency region may be determined as being conforming product. In particular, when the ratio of the resistance in the ultra-high frequency region to the resistance in the high frequency region ranges from 1.2 to 2.0, the quality of the all-solid-state battery which is a target for the determination of conforming product may be especially superior.

According to the present disclosure, the initial capacitance of the unit cell determined as being conforming product may be at least 90% of a design capacitance of the unit cell. Preferably, the initial capacitance of the unit cell may be at least 92%, at least 93%, at least 94%, at least 95%, at least 96%, at least 97%, or at least 98% of the design capacitance of the unit cell. The unit cell determined as being conforming product substantially shows an initial capacitance significantly approximate to an initial capacitance estimated in design, which indicates superior performance of the unit cell.

Hereinafter, example embodiments of the present disclosure will be described in more detail. However, the following embodiment is provided only for the illustrative purpose, and the scope of the present disclosure is not limited to the following embodiment.

### EXAMPLE EMBODIMENTS

The conforming product of unit cells of three types of all-solid-state batteries different from each other was determined through the method for sorting the all-solid-state battery of conforming product. The resistance of each unit cell was measured after sequentially stacking a cathode, a solid electrolyte layer, and an anode, packaging the stack structure in a pouch, and performing a pressing process for the stack structure using a WIP plate, and Hioki's IM3590 was used as a resistance measuring equipment. To measure the resistance, the high frequency region was set in the range of 1 kHz to 10 kHz, and the ultra-high frequency region was set in the range 10 kHz to 100 kHz. When a resistance in the high frequency region ranged from 100 mΩ to 150 mΩ and a resistance in the ultra-high frequency region ranged from 80 mΩ to 200 mΩ, the unit cell having the resistances in the high frequency region and in the ultra-high frequency region was determined as being conforming product.

The determination result for conforming product is organized as shown in Table 1.

TABLE 1

| | Cell 1 | Cell 2 | Cell 3 |
|---|---|---|---|
| High frequency resistance (mΩ) | 147.3 | 102.8 | 93.1 |
| Ultra-high frequency resistance | 345.3 | 154.6 | 40.4 |
| (mΩ) | | | |
| Conforming product state | Failure | Conforming product | Failure |
| Initial capacitance (%) as | 95.1 | 98.5 | 82.3 |
| compared to design capacitance | | | |

Meanwhile, the initial capacitance (%) as compared to design capacitance in Table 1 may be calculated by multiplying a value, which is obtained by dividing a measured capacitance by a cell capacitance theoretical value, by 100%. Meanwhile, when the cathode is designed with limitations, the cell capacitance theoretical value may be calculated by subtracting a cathode irreversible capacitance from a cathode charging amount. When the anode is designed with limitations, the cell capacitance theoretical value may be calculated by subtracting the cathode irreversible capacitance from an anode charging amount.

As organized in Table 1, cell #2 sorted as a cell of conforming product through the method for sorting the all-solid-state battery of conforming product according to the present disclosure was recognized as substantially having an initial capacitance which is 98.5% of the design capacitance, which refers to that the initial capacitance of cell #2 substantially approximates to the real design capacitance. Meanwhile, cell #1 determined as a failed cell was recognized as having a significantly high resistance in the ultra-high frequency, which refers to that ion conductivity of cell is excessively low. Cell #3 determined as a failed cell like cell #1 was recognized as having an initial capacitance excessively lower than the design capacitance, which is determined as being caused due to micro-short and self-discharge as an insulating characteristic is not ensured. In more detail, cell #1 is significantly higher than cell #2, which is determined as being conforming product, in the ultra-high resistance, which may be an index indicating the resistance on the interface. Accordingly, it may be derived that a contact on a solid interface inside the cell is failed. As cell #3 is low in the high frequency resistance, which is an index indicating the cell part resistance, the short failure may be caused inside the cell.

Accordingly, when employing the method for sorting the all-solid-state battery of conforming product according to the present disclosure, whether the all-solid-state battery has conforming product may be easily determined by simply measuring the resistance of a unit cell after the pressing process, without calculating the initial capacitance as compared to the real design capacitance.

The present disclosure has a technical meaning in that the present disclosure provides the method for sorting an all-solid-state battery of conforming product, which is specialized for the all-solid-state battery, instead of a conforming product determining manner specially suggested for the conventional lithium ion battery. When employing the method for sorting the all-solid-state battery of conforming product according to the present disclosure, the failure of the all-solid-state battery may be simply determined, thereby ensuring the uniform and superior quality of the all-solid-state battery obtained in the final stage.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A method for sorting an all-solid-state battery of conforming product, the method comprising:
measuring a resistance of a unit cell in a high frequency region and a resistance of the unit cell in an ultra-high frequency region after pressing the unit cell in which a cathode, a solid electrolyte layer, and an anode are stacked; and
determining whether the unit cell is conforming product, based on the resistances of the unit cell measured in the high frequency region and the ultra-high frequency region.

2. The method of claim 1, wherein the high frequency region is a frequency region ranging about from 0.01 kHz to 10 KHz.

3. The method of claim 1, wherein the high frequency region is a frequency region ranging about from 2 kHz to 4 kHz.

4. The method of claim 1, wherein the ultra-high frequency region is a frequency region ranging about from 10 kHz to 100 kHz.

5. The method of claim 1, wherein the ultra-high frequency region is a frequency region ranging about from 30 kHz to 70 KHz.

6. The method of claim 1, wherein the unit cell is determined to be a conforming product when the measured resistance of the unit cell in the high frequency region ranges from about 100 mΩ to about 150 mΩ.

7. The method of claim 1, wherein the unit cell is determined to be a conforming product when the measured resistance of the unit cell in the ultra-high frequency region ranges from about 80 mΩ to about 200 mΩ.

8. The method of claim 1, wherein the unit cell is determined to be a conforming product when the measured resistance of the unit cell in the ultra-high frequency region is greater than the measured resistance in the high frequency region.

9. The method of claim 1, wherein the unit cell is determined to be a conforming product when a ratio of the measured resistance in the ultra-high frequency region to the measured resistance in the high frequency region ranges from about 1.2 to about 2.0.

10. The method of claim 1, wherein the unit cell determined as being conforming product has an initial capacitance which is at least 90% of a design capacitance of the unit cell.

11. A method for sorting an all-solid-state battery of conforming product, the method comprising:
stacking a cathode, a solid electrolyte layer, and an anode to form a unit cell;
pressing the unit cell;
measuring a resistance of the pressed unit cell in a high frequency region and a resistance of the pressed unit cell in an ultra-high frequency region; and
determining whether the pressed unit cell is a conforming product based on the measured resistances in the high frequency region and the ultra-high frequency region.

12. The method of claim 11, wherein the high frequency region is a frequency region ranging from about 2 kHz to about 4 kHz.

13. The method of claim 11, wherein the ultra-high frequency region is a frequency region ranging from about 30 kHz to about 70 kHz.

14. The method of claim 11, wherein the pressed unit cell is determined to be the conforming product when a resistance of the pressed unit cell in the high frequency region is from about 100 mΩ to about 150 mΩ.

15. The method of claim 11, wherein the pressed unit cell is determined to be the conforming product when a resistance of the pressed unit cell in the ultra-high frequency region is from about 80 mΩ to about 200 mΩ.

16. The method of claim 11, wherein the pressed unit cell is determined to be the conforming product when a measured resistance in the ultra-high frequency region is greater than a measured resistance in the high frequency region.

17. The method of claim 11, wherein the pressed unit cell is determined to be the conforming product when a ratio of the resistance in the ultra-high frequency region to the resistance in the high frequency region ranges from about 1.2 to about 2.0.

18. A method of manufacturing an all-solid-state battery, the method comprising:
(a) stacking a cathode, a solid electrolyte layer, and an anode to form a stack structure;
(b) pressing the stack structure;
(c) measuring a resistance of the pressed stack structure in a high frequency region and a resistance of the pressed stack structure in an ultra-high frequency region;
(d) sorting the pressed stack structure as a conforming product or a non-conforming product based on the measured resistances in the high frequency region and the ultra-high frequency region; and
(e) performing one or more subsequent battery-manufacturing steps on the pressed stack structure sorted as the conforming product.

19. The method of claim 18, wherein the pressing is performed at a pressure of about 450 MPa and a temperature of about 100° C.

20. The method of claim 18, further comprising discarding or reworking any pressed stack structure sorted as the non-conforming product prior to performing the one or more subsequent battery-manufacturing steps.
